(19) United States
(12) Patent Application Publication
(10) Pub. No.: US 2009/0261990 A1
(43) Pub. Date: Oct. 22, 2009

(54) MANUAL PULSE GENERATOR

(75) Inventors: CHIEN-CHUNG WU, Tu-Cheng (TW); CHING-CHENG YANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXNUM TECHNOLOGY CO., LTD., Tucheng City (TW)

(21) Appl. No.: 12/257,358

(22) Filed: Oct. 23, 2008

(30) Foreign Application Priority Data
Apr. 18, 2008 (CN) 200810301208.1

(51) Int. Cl. H03K 17/94

(52) U.S. Cl. 341/20

(57) ABSTRACT

A manual pulse generator includes an operating region receiving contact to generate a contact signal, a touch sensor, and a programmable chip. The touch sensor is capable of generating electrical signals according to the contact signal. The programmable chip is electrically connected to the touch sensor to receive electrical signals from the touch sensor and generate pulse signals to control a motor accordingly.

### BACKGROUND

1. Technical Field

The present disclosure generally relates to manual pulse generators, and particularly to a manual pulse generator used in a computer numerical control device.

2. Description of Related Art

Manual pulse generators are device normally associated with computer numerical control (CNC) or other devices involved in positioning. The manual pulse generator generates electrical pulses sent to a CNC device controller. The controller moves a functional part of the CNC device a predetermined distance for each pulse.

Referring to FIG. 6, a conventional manual pulse generator is used in a CNC device tool. The conventional manual pulse generator includes a rotor 11, an axis selector 12 selecting one of the axes X, Y, and Z, and a magnification selector 13 to control speed of the CNC device tool, such as X1, X10, and X100. The rotor 11 is configured to generate pulse signals to control the CNC device tool. Inclusion of the rotor 11, along with other elements, requires considerable size and weight for the manual pulse generator, making it difficult to use for prolonged periods.

Therefore, what is needed, is a functional yet compact and light manual pulse generator addressing the described limitations.

### BRIEF DESCRIPTION OF THE DRAWINGS

FIG. 1 is an isometric view of a manual pulse generator in accordance with an embodiment of the disclosure, the manual pulse generator including functional keys and an operating region;

FIG. 2 is a schematic diagram of the manual pulse generator of FIG. 1;

FIG. 3 is an isometric view of the functional keys and the operating region of the manual pulse generator of FIG. 1;

FIG. 4 is an isometric view of the manual pulse generator of FIG. 1 in a first deployment;

FIG. 5 is an isometric view of the manual pulse generator of FIG. 1 in a second deployment; and

FIG. 6 is an isometric view of a conventional manual pulse generator.

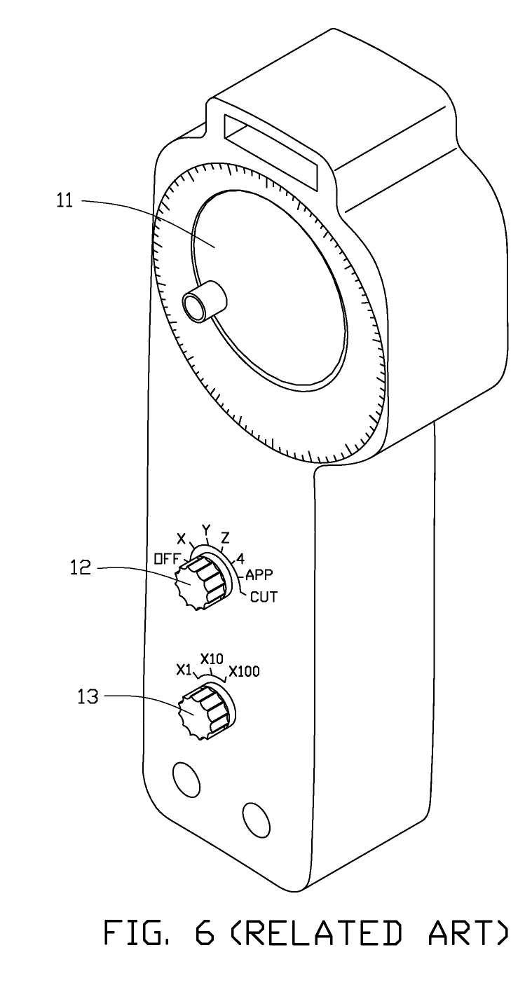

### DETAILED DESCRIPTION

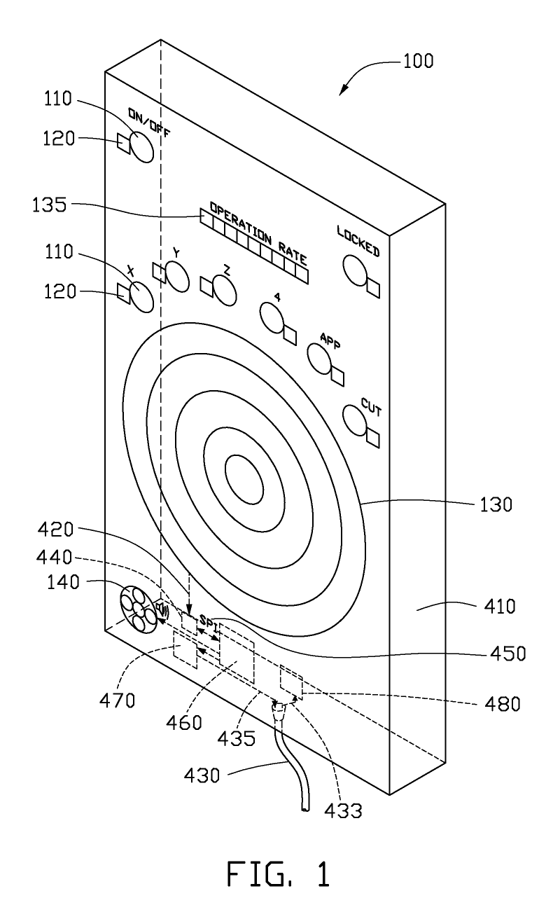

Referring to FIG. 1, a manual pulse generator 100 in accordance with an embodiment of the disclosure includes a plurality of functional keys 110, a plurality of corresponding key indicators 120, an operating region 130, a plurality of corresponding operating indicators 135, a buzzer 140, a printed circuit board (PCB) 410, a first signal line 420, a second signal line 430, a touch sensor 440, a serial peripheral interface (SPI) 450, a programmable chip 460, a communication interface 470, and a power unit 480. The functional keys 110, the key indicators 120, the operating region 130, the operating indicators 135, and the buzzer 140 are located on a front surface of the manual pulse generator 100. The PCB 410 is arranged inside the manual pulse generator 100. The first signal line 420, the second signal line 430, the touch sensor 440, the serial peripheral interface (SPI) 450, the programmable chip 460, the communication interface 470, and the power unit 480 are arranged on a rear surface of the manual pulse generator 100.

The functional keys 110 include a first axis selector X, a second axis selector Y, a third axis selector Z, a fourth axis selector “4”, a fifth axis selector APP, a sixth axis selector CUT, a switch ON/OFF, and a lock LOCKED. The functional keys 110 are configured to select a drive axis in a CNC device to be controlled by the manual pulse generator 10.

The key indicators 120 are configured to show the processing function when a corresponding functional key 110, such as the first axis selector X, is activated. The operating region 130 is divided into a plurality of parts, each for a different wave band. The operating indicators 135 are configured to display the magnification of the pulse correspondingly when the operating region 130 is operated in different wave bands. The buzzer 140 generates audio signals with different frequencies according to pulse signals from the programmable chip 460.

The first signal line 420 is configured to transmit electrical signals from the functional keys 110 and the operating region 130 to the touch sensor 440. In the current embodiment, the touch sensor 440 is a capacitive touch sensor.

The SPI 450 is configured to transfer electrical signals from the touch sensor 440 to the programmable chip 460. The programmable chip 460 is programmed in hardware description language (HDL). In the current embodiment, the programmable chip 460 is a field programmable gate array (FPGA) or a complex programmable logic device (CPLD).

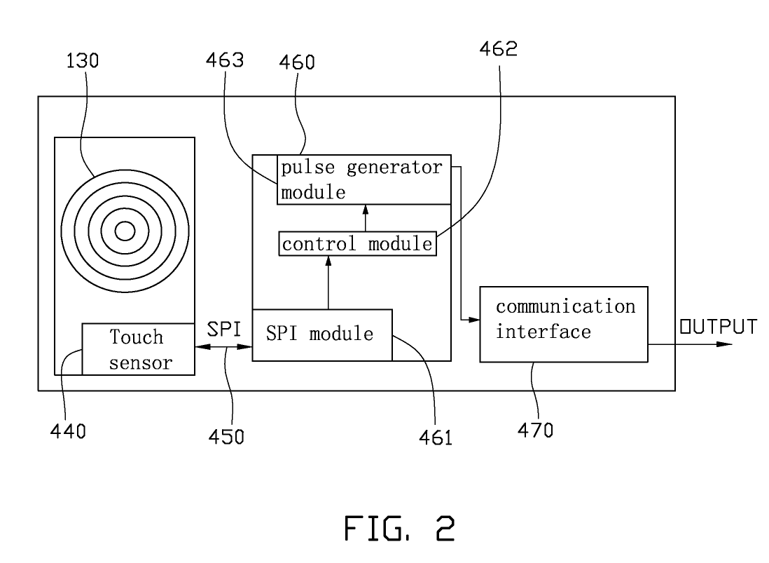

Referring to FIG. 2, the programmable chip 460 includes a SPI module 461, a control module 462, and a pulse generator module 463. The SPI module 461 is configured to transfer electrical signals from the SPI 450 to the control module 462. The control module 462 is configured to receive electrical signals from the SPI module 461 and convert electrical signals to frequency signals. The pulse generator module 463 is configured to receive the frequency signals, and convert the frequency signals to pulse signals. The communication interface 470 is configured to receive the pulse signals. The pulse signals are directly related to the wave band rate of the operating region 130. The communication interface 470 is also configured to receive the pulse signals from the programmable chip 460, and output differential pulse signals correspondingly. In the current embodiment, the communication interface 470 is an RS-232 interface, an RS-422 interface, or an RS-485 interface.

The second signal line 430 includes a direct current line 433 and a pulse line 435. The direct current line 433 is configured to supply a direct current to the power unit 480. The pulse line 435 is configured to receive the pulse signals from the communication interface 470, and transfer the pulse signals to a motor (not shown).

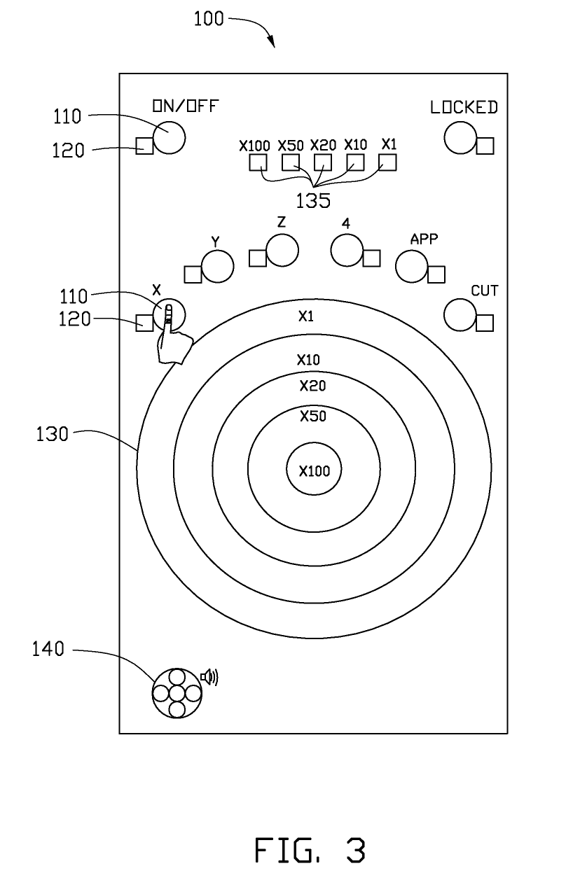

Referring to FIG. 3, when one of the functional keys 110, such as the first axis selector X, is activated, an electrical signal is transferred to the touch sensor 440 via the first signal line 420. The touch sensor 440 transfers the electrical signal to the pulse generator module 463 via the SPI 450, the SPI module 461, and control module 462 in series. The pulse generator module 463 converts the electrical signal to a pulse signal, and transfers the pulse signal to the communication interface 470 to control an axis X of the motor. The pulse signal from the pulse generator module 463 is also transferred to the buzzer 140, and the buzzer 140 generates a corresponding audio signal.

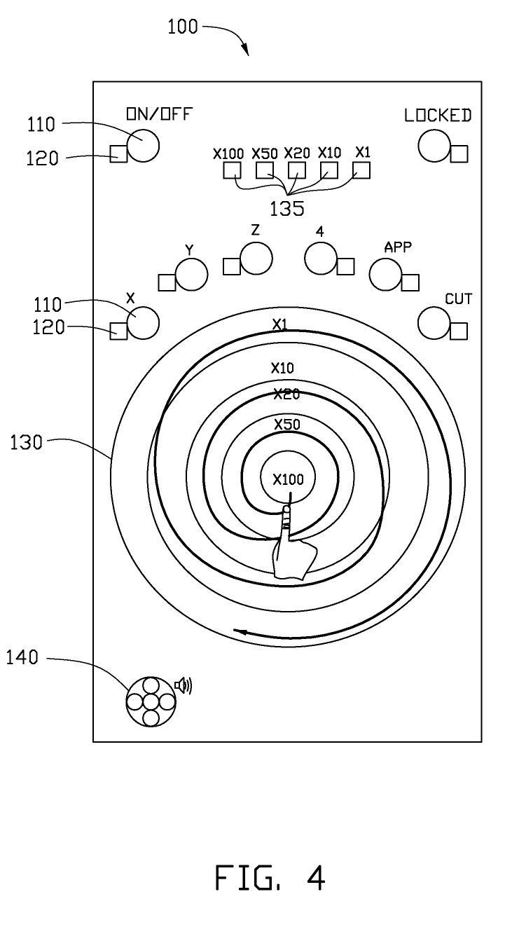

Referring to FIG. 4, when the operating region 130 is activated, such as being contacted in a clockwise motion, a clockwise signal is transferred to the programmable chip 460 via the first signal line 420, the touch sensor 440, and the SPI 450 in series. In the current embodiment, the programmable chip 460 is set to output a positive rotation signal when receiving the clockwise signal. The positive rotation signal is transferred to the motor via the SPI module 461, the control module 462, the pulse generator module 463, the communication interface 470, and the pulse line 435. As a result, the motor rotates in a clockwise motion. The buzzer 140 generates a positive pulse audio signal according to the positive rotation signal.

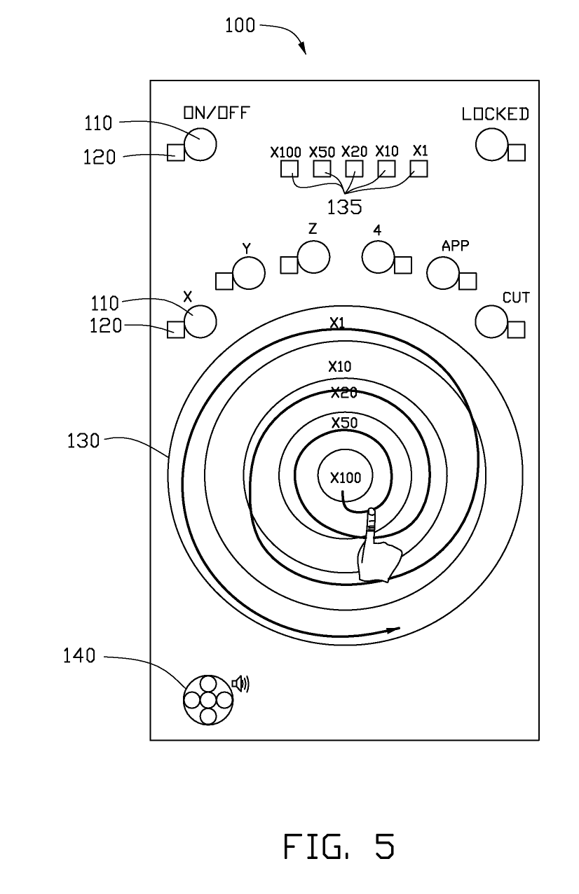

Referring to FIG. 5, similar to FIG. 4, when the operating region 130 is active, such as being contacted in a counter-clockwise motion, a counter-clockwise signal is transferred to the programmable chip 460 via the first signal line 420, the touch sensor 440, and the SPI 450 in series. The programmable chip 460 outputs a negative rotation signal to the motor via the SPI module 461, the control module 462, the pulse generator module 463, the communication interface 470, and the pulse line 435. As a result, the motor is rotated in a counter-clockwise motion. The buzzer 140 generates a negative pulse audio signal according to the negative rotation signal.

The operating region 130 generates electrical signals with different magnification when different parts of the operating region 130 are in operation. In the current embodiment, the operating region 130 includes five parts and the skip signals include five magnifications, “X1”, “X10”, “X20”, “X50”, and “X100” correspondingly. When a first part of the operating region 130 is in operation, the operating region 130 generates a skip signal with the magnification of X1.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the invention and their practical application so as to enable others skilled in the art to utilize the disclosure and various embodiments and with various modifications as are suited to the particular use contemplated. Alternative embodiments will become apparent to those skilled in the art to which the disclosure pertains without departing from its spirit and scope. Accordingly, the scope of the disclosure is defined by the appended claims rather than the foregoing description and the exemplary embodiments described therein.

What is claimed is:

1. A manual pulse generator comprising:
an operating region receiving contact to generate a contact signal;
a touch sensor generating electrical signals according to the generated contact signal; and
a programmable chip electrically connected to the touch sensor to receive the electrical signals therefrom, and generate pulse signals to control a motor accordingly.

2. The manual pulse generator as claimed in claim 1, wherein the programmable chip comprises a serial peripheral interface (SPI) module, a control module, and a pulse generator module; the SPI module is configured to receive the electrical signals from the touch sensor, and transfer the electrical signals to the control module; the control module is configured to generate frequency signals according to the electrical signals, and transfer the frequency signals to the pulse generator module; the pulse generator module is configured to generate the pulse signals according to the frequency signals.

3. The manual pulse generator as claimed in claim 1, wherein the programmable chip is a field programmable gate array or a complex programmable logic device.

4. The manual pulse generator as claimed in claim 1, wherein the touch sensor is a capacitive touch sensor.

5. A manual pulse generator capable of controlling a motor, comprising:
a plurality of functional keys capable of selecting a rotational axis of the motor;
a touch sensor capable of generating electrical signals according to the selected axis; and
a programmable chip electrically connected to the touch sensor, and capable of receiving the electrical signals from the touch sensor, and generating pulse signals to control the selected axis of the motor accordingly.

6. The manual pulse generator as claimed in claim 5, wherein the programmable chip comprises a serial peripheral interface (SPI) module, a control module, and a pulse generator module, and wherein the SPI module is configured to receive the electrical signals from the touch sensor, and transfer the electrical signals to the control module; the control module is configured to generate frequency signals according to the electrical signals, and transfer the frequency signals to the pulse generator module; and the pulse generator module is configured to generate the pulse signals according to the frequency signals.

7. The manual pulse generator as claimed in claim 5, wherein the programmable chip is a field programmable gate array or a complex programmable logic device.

8. The manual pulse generator as claimed in claim 5, wherein the touch sensor is a capacitive touch sensor.
